(19) United States
(12) Patent Application Publication
(10) Pub. No.: US 2023/0420274 A1
(43) Pub. Date: Dec. 28, 2023

(54) Radiatively-Cooled Substrate Holder

(71) Applicant: TEL Manufacturing and Engineering of America, Inc., Chaska, MN (US)

(72) Inventor: Kevin Siefering, Excelsior, MN (US)

(21) Appl. No.: 17/846,867

(22) Filed: Jun. 22, 2022

(51) Int. Cl. H01L 21/67; H01L 21/66; H01L 21/324; H01L 21/683

(52) U.S. Cl. CPC H01L 21/67103; H01L 22/20; H01L 21/324; H01L 21/67248; H01L 21/6833

(57) ABSTRACT

A method of cooling a substrate during processing includes processing a substrate supported by a substrate holder where the substrate is heated by the processing, cooling the substrate while processing the substrate by radiating heat from the substrate holder, and maintaining the substrate at a steady temperature to within a tolerance while processing the substrate. The substrate is maintained at the steady temperature by heating the substrate holder such that heat transferred from the substrate by radiating heat from the substrate holder substantially balances heat transferred to the substrate by processing the substrate and by heating the substrate holder.

### TECHNICAL FIELD

The present invention relates generally to substrate processing, and, in particular embodiments, to methods, apparatuses, and systems for substrate processing using radiative cooling.

### BACKGROUND

Device formation within microelectronic workpieces generally involves a series of manufacturing techniques including formation, patterning, and removal of a number of layers of material on a substrate. Cooling of the substrate can be important during device formation as processing the substrate may also heat the substrate. Elevated wafer temperatures as well as temperature non-uniformity can lead to device defects, variability, and failure.

Some processing techniques process a selected portion of the substrate rather than processing the entire substrate simultaneously. For example, a surface of the substrate may be exposed to a beam focused such that it is localized in a spot that is much smaller than the surface of the substrate and that beam is scanned laterally across the substrate surface. Such localized scanning techniques may be even more prone to cause uneven heating across a substrate surface.

### SUMMARY

In accordance with an embodiment, a method of cooling a substrate during processing includes processing a substrate supported by a substrate holder where the substrate is heated by the processing, cooling the substrate while processing the substrate by radiating heat from the substrate holder, and maintaining the substrate at a steady temperature to within a tolerance while processing the substrate. The substrate is maintained at the steady temperature by heating the substrate holder such that heat transferred from the substrate by radiating heat from the substrate holder substantially balances heat transferred to the substrate by processing the substrate and by heating the substrate holder.

In accordance with another embodiment, a substrate holder includes a chuck configured to immobilize a substrate at a first side of the chuck comprising a first material, a heater disposed on or in the chuck and configured to heat the substrate, and a second material disposed at a second side of the chuck opposing the first side. The second material includes an exposed surface configured to cool the substrate by emitting thermal radiation. The emissivity of the first material is lower than the emissivity of the second material.

In accordance with still another embodiment, a substrate processing apparatus includes a vacuum chamber, an electrostatic chuck disposed in the vacuum chamber, a heater integrated with the electrostatic chuck, and a mechanical arm attached to the electrostatic chuck. The electrostatic chuck has no liquid cooling mechanism. The electrostatic chuck is configured to clamp a substrate to an upper surface of the electrostatic chuck facing a localized processing source. The heater is configured to heat the substrate while processing the substrate. The mechanical arm is configured to move the substrate laterally relative to the localized processing source to process the substrate.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a support assembly including a partial-diameter substrate holder equipped with an overscan shield;

FIGS. 2A, 2B, and 2C illustrate lateral substrate temperature variations for three types of substrate holders across five successively processed substrates, where FIG. 2A shows a partial-diameter substrate holder, FIG. 2B shows a full-diameter substrate holder, and FIG. 2C shows a heated full-diameter substrate holder;

FIG. 3 illustrates a method of cooling a substrate during processing by heating the substrate in accordance with embodiments of the invention;

FIG. 4 illustrates an example support assembly including a substrate holder and a heating element configured to radiatively cool a substrate in accordance with embodiments of the invention;

FIG. 5 illustrates an example support assembly including a substrate holder supporting a substrate and including a material with an emissivity that is higher than the emissivity of the material facing the substrate in accordance with embodiments of the invention;

FIG. 6 illustrates an example support assembly including a substrate holder and a heating element disposed between the substrate holder and a bottom cover in accordance with embodiments of the invention;

FIG. 7 illustrates an example support assembly including a substrate holder and an overscan shield at least partially underlying a full-diameter substrate holder in accordance with embodiments of the invention;

FIG. 8 illustrates an example support assembly including a substrate holder with an integrated overscan shield in accordance with embodiments of the invention;

FIG. 9 illustrates another example support assembly including a substrate holder with an integrated overscan shield in accordance with embodiments of the invention;

FIGS. 10A and 10B illustrate an example support assembly including a substrate holder attached to a mechanical arm configured to move the substrate laterally relative to a processing source during processing in accordance with embodiments of the invention, where FIG. 10A is a side view of the support assembly and FIG. 10B illustrates a bottom view of the support assembly;

FIG. 11 illustrates a substrate processing apparatus including a substrate holder configured to radiatively cool a substrate while the substrate is being processed by heating the substrate holder during the processing in accordance with embodiments of the invention; and

FIG. 12 illustrates another example substrate processing apparatus configured to radiatively cool a substrate while the substrate is being processed where the processing utilizes a mechanical arm to move the substrate laterally relative to a processing source in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Substrate processing frequently results in heating of the substrate being processed. For example, plasma processes may impart significant thermal energy to the substrate (e.g. a wafer). Left unchecked, substrate heating may cause a variety of undesirable processing defects and variations due to global and local temperature extremes and nonuniformity. A common type of substrate in the microelectronics industry is a wafer (e.g. a semiconductor wafer). The term wafer may be used herein to describe various concepts to improve comprehension with the understanding that these concepts frequently also apply to the general category of substrates.

If the temperature in a region of a wafer departs from certain process-dependent temperature ranges, the process may fail to produce the desired processing outcome in that region (possibly affecting surrounding regions as well). Moreover, process uniformity is desirable both across the surface of an individual wafer (cross-wafer uniformity) as well as between wafers being processed (wafer-to-wafer uniformity).

Processing techniques that process only a portion of the wafer at a given time, such as scanning techniques, can present an even greater challenge than techniques that process the entire surface of the wafer simultaneously because wafer heating is also localized. One example of such a localized processing technique is a partial plasma etch process that utilizes a beam of plasma focused on the wafer to process the wafer according to a desired pattern (e.g. a raster pattern).

Partial plasma etching may impart significant thermal energy to the wafer, locally heating the substrate in areas where it is not supported (and thus not cooled) by a substrate holder (e.g. a chuck), which may conduct heat away from the substrate. This can cause both cross-wafer and wafer-to-wafer temperature nonuniformity during processing, which in turn may lead to etch nonuniformity.

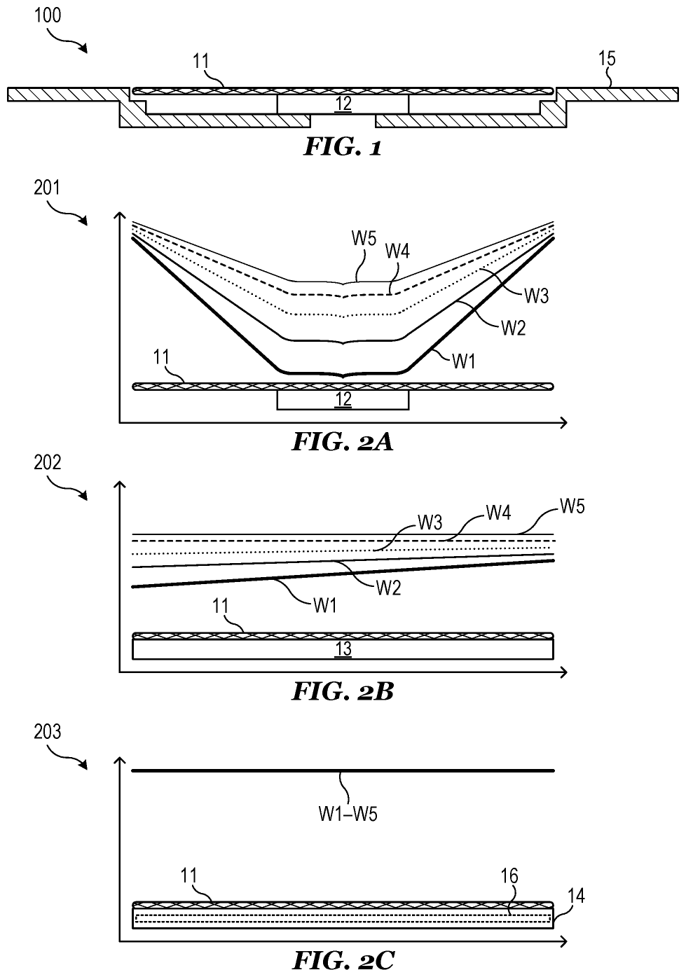

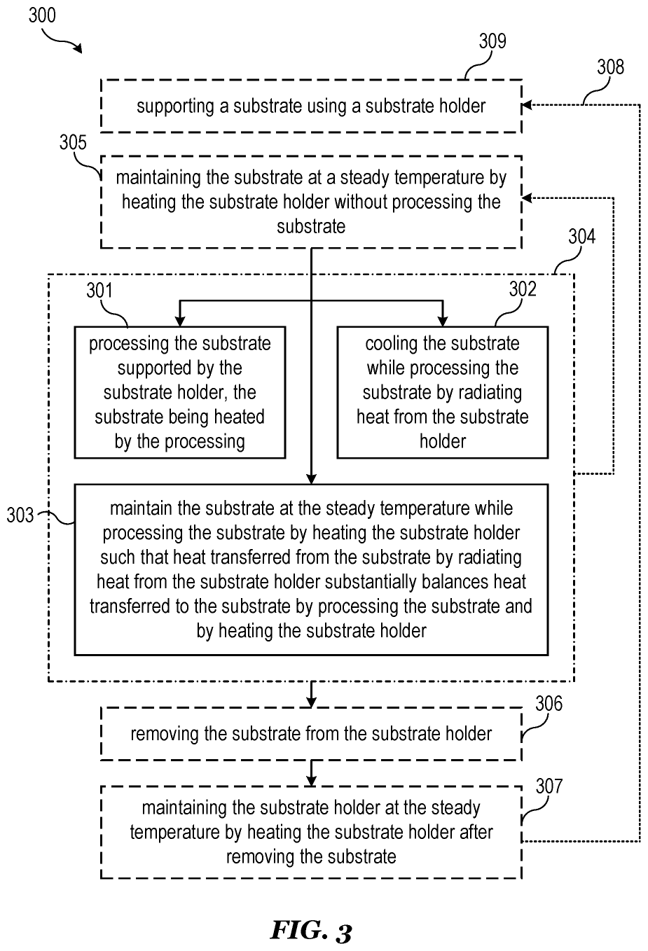

In many applications, the substrate holder supporting the substrate is the primary mechanism for controlling the temperature of the substrate. As a result, the design of the substrate holder may influence the temperature profile of a substrate supported by the substrate holder. FIGS. 1, 2A, 2B, and, 2C are used to demonstrate some effects that certain substrate holder features may have on cross-wafer uniformity and wafer-to-wafer uniformity. FIGS. 2A, 2B, and 2C illustrate lateral substrate temperature variations for three types of substrate holders across five successively processed substrates, where FIG. 2A shows a partial-diameter substrate holder, FIG. 2B shows a full-diameter substrate holder, and FIG. 2C shows a heated full-diameter substrate holder.

FIG. 1 illustrates a support assembly 100 including a partial-diameter substrate holder 12 equipped with an overscan shield 15. The partial-diameter substrate holder 12 is configured to support a substrate (e.g. a wafer 11). The support assembly 100 may be a specific implementation of a support assembly 100 that is usable in a partial plasma etch process of the wafer 11.

In this specific example, the partial-diameter substrate holder 12 is an electrostatic chuck (ESC) and the wafer 11 is held in place by an electrostatic force generated by applying high voltages (positive and negative) to electrodes in the electrostatic chuck. The partial plasma etch process may move the wafer 11 relative to a stationary localized plasma source. The electrostatic force (i.e. clamping force) may be important to prevent the wafer 11 from slipping on the chuck as the chuck is rapidly accelerated and decelerated in the lateral direction during scanning under the plasma.

The overscan shield 15 is provided which extends the horizontal plane created by the wafer 11 beyond the wafer perimeter. When the wafer 11 is scanned under the plasma, the scan may purposefully drive over the edge of the wafer 11 and onto the overscan shield 15 before the scan reverses direction and increments in the direction perpendicular to the scan to scan across the wafer again in the opposite direction.

The diameter of the partial-diameter substrate holder 12 is significantly smaller than the diameter of the wafer 11. Consequently, the wafer 11 overhangs the chuck around the perimeter in this specific example. As the wafer 11 is processed by scanning under the plasma source, the interaction with the plasma imparts thermal energy locally to the area of the wafer directly under the plasma nozzle, heating the wafer surface. Additionally, the etching reaction occurring on the wafer surface may also be exothermic, resulting in more heat, some of which is conducted into the wafer 11.

In areas where the wafer 11 overhangs the edge of the partial-diameter substrate holder 12, that thermal energy may be more difficult to dissipate, and the wafer 11 can gain temperature rapidly. For example, in areas where a chuck supports the wafer, the thermal energy can more easily dissipate through conduction into the chuck.

This can result in temperature nonuniformity, as shown in qualitative graph 201 of FIG. 2A where the perimeter of the wafer 11 is much hotter than central area of the wafer 11 (i.e. the temperature of the wafer surface increases more rapidly with increased distance from the chuck contact area). The etch rate of the plasma on the wafer surface may be affected by the temperature of the substrate surface (e.g. a strong increasing function of the surface temperature). Thus, for the temperature profile shown, the perimeter may undesirably etch faster than the cooler central areas. This can cause unacceptably high cross-wafer nonuniformity of the etch.

When the processing chamber within which the partial plasma etch is performed has been idle for some time, the wafer chuck may cool slowly to ambient temperature. This cooling may occur through slow conduction of heat through the mechanical arm that supports the chuck or through slow radiation of heat to the cooler surrounding chamber walls.

As shown in FIG. 2A, when the first wafer W1 is processed, the chuck surface is relatively cool. Heat from the wafer readily conducts into it, cooling the wafer locally in the contact area. The heat conducted into the chuck warms the chuck itself, so that when the second wafer W2 is processed, it rests on a chuck that is at a substantially warmer temperature than the first wafer W1. That is, the chuck temperature increases from wafer to wafer as the chuck absorbs thermal energy faster than it is dissipated. Heat is thus conducted from the chuck into the wafer before processing and during processing.

The third wafer W3 similarly sees a higher temperature, and similar effects can be seen for the fourth wafer W4 and fifth wafer W5, lessening somewhat with higher initial chuck temperature. Thermal energy generated from the plasma less readily conducts into the chuck because the chuck is warmer, so the temperature of the chuck gradually rises as more and more wafers are processed until it reaches a pseudo steady state or until processing is paused and it gradually starts to cool again. This variability in the chuck temperature may drive unacceptably high wafer-to-wafer nonuniformity of the etch.

One potential disadvantage of lower wafer temperatures is the adsorption of compounds on the wafer surface during processing that may be present afterwards. For example, wafers may leave the processing chamber after the partial plasma etch process with sulfur compounds adsorbed on the wafer surface. These compounds may be undesirable for various reasons, including toxicity. In the case of sulfur, the adsorbed compounds may cause foul odor that is detectable after the wafer has been removed from the processing chamber, such as when the wafer is in a Front Opening Unified Pod (FOUP).

Referring now to FIG. 2B, qualitative graph 202 demonstrates the difference in the cross-wafer temperature profile when a full-diameter substrate holder 13 is used. The full-diameter substrate holder 13 has a diameter at least as large as the wafer 11, and may be the same size, as shown. The temperature curves of graph 202 indicate that this configuration may have greatly improved cross-wafer temperature uniformity over the partial-diameter substrate holder 12 of FIG. 2A due to the continuous contact of all portions of the wafer 11 with the full-diameter substrate holder 13. Additionally, the thermal mass of the full-diameter substrate holder 13 is higher, advantageously resulting in less wafer-to-wafer temperature increase.

Although the full-diameter substrate holder 13 improves cross-wafer temperate uniformity, it may still be vulnerable to asymmetries in other parts of the support assembly. For example, the lower temperature of the wafers at the left side of the graph 202 may be the result of a mechanical arm attached to the full-diameter substrate holder 13 and extending leftward from the central area of the full-diameter substrate holder 13. Heat may be transferred through the mechanical arm, resulting in cooler temperatures closer to the arm. The cooler temperatures may also increase undesirable adsorbed compounds such as sulfur in comparison to the partial-diameter substrate holder 12, which results in a higher average wafer temperature.

Temperature variation from one side of the wafer to the other can also be caused by the rastering process which starts on one side of the wafer and ends on the other side. Since some heat conducts laterally through the substrate holder during processing, the side of the wafer that is processed last may see a somewhat higher temperature than the side that is processed first.

It should be noted that increasing the time between processed wafers can also be used to lessen or eliminate wafer-to-wafer nonuniformity. However, this is typically impractical due to the lengthy timescales needed to allow the processing heat to dissipate fully from the substrate holder. Such losses in throughput would be an unacceptable solution in many applications.

One method of reducing cross-wafer nonuniformity is demonstrated in qualitative graph 203 of FIG. 2C showing a heated full-diameter substrate holder 14 that includes a heater 16. In contrast, the substrate holders of FIGS. 2A and 2B are not heated. The heater 16 can elevate the wafer 11 to a pseudo steady state by transferring additional thermal energy into the wafer 11 without relying on the heat to be slowly added through iterations of wafer processing.

Beneficially, the first wafer W1 has substantially the same temperature profile as the fifth wafer W5 and so on. Additionally, because the heated full-diameter substrate holder 14 can be quickly heated to a pseudo steady state prior to processing the first wafer, cross-wafer uniformity is also improved.

However, the specific value of the pseudo steady state temperate for a given implementation is dependent on the capability of the support assembly to passively or actively cool the supported wafer. Insufficient cooling will cause the value to be higher than the upper boundary of the acceptable temperature range for a given process. Some or even most wafer cooling options may be unavailable due to practical considerations, process specifics, cost, complexity, and other design considerations.

One common technique for cooling a wafer on a wafer chuck (i.e. a substrate support) is to circulate a liquid through the chuck to transport heat away from the wafer. Liquid cooling mechanisms conduct thermal energy from the wafer to a liquid circulated through a closed system. The liquid then transfers the heat away from the chuck via forced liquid advection to be dissipated elsewhere.

However, liquid cooling requires plumbing to be included in the chuck, which may be complicated and prone to leaks. One specific application where liquid cooling may be particularly impractical is for processes using a non-stationary wafer chuck, such as scanning techniques like the partial plasma etch process referenced above. In order to scan the surface of the wafer, the chuck may laterally move and/or rotate at very high velocities and with large accelerations and decelerations.

A liquid cooling solution in such a system compatible with the lateral wafer movement would require flexible plumbing in a mechanical arm capable of reliably withstanding the extreme movements. For compatibility with a rotated substrate, indirect contact (e.g. using gas contact such as He) would need to be used to provide the thermal conduction between the rotating and stationary portions of the wafer chuck. The inclusion of gas into the wafer chuck (e.g. an ESC) introduces more complexity and further possibilities for leaks. Helium may also be expensive, as evidenced by recent global shortages.

Convective cooling using a background gas is another technique that may be used to cool a wafer during processing. Yet this may also not be an option since the background gas increases the pressure in the processing chamber, which could adversely affect the process performance (e.g., etch spot size, shape or etch rate) and could introduce additional chemistry that may impact the process.

Another form of wafer cooling that uses a third heat transfer method is radiative cooling. In contrast to liquid cooling which uses a combination of heat conduction and heat advection, radiative cooling relies on surfaces to radiate heat into the surrounding environment. The ability of a support assembly to dissipate heat through radiative heat transfer depends on the surface area, temperature, and emissivity of exposed surfaces (as well as the impact of the surrounding environment, e.g. the chamber, which will be assumed insignificant enough to be ignored for the following first order calculations, but could be a design consideration for specific implementations of a processing environment).

For example, a simplified form of the radiative transfer equation for the radiative heat flux can be written as q=εσT⁴ where q is the radiative heat flux in W/m², ε is the emissivity of the surface of an object, σ is the Stefan-Boltzmann constant, and T is the absolute temperature of the object. Thus, the total thermal energy in watts radiated by the object is Q=qA where A is the total surface area of the object.

These equations demonstrate that the capability of a substrate holder (e.g. the chuck) transfer heat via radiation can be increased by increasing the temperature of the substrate holder, the emissivity of the surfaces, and the surface area of the substrate holder. Notably, the total radiated thermal energy is proportional to T⁴ allowing a large increase in Q in response to a much smaller increase in T. This feature of radiative heat transfer can be advantageously leveraged to cool a substrate during processing.

The temperature rise near the unsupported wafer edge (shown qualitatively above with respect to the partial-diameter substrate holder 12 in FIG. 2A, for example) indicate that for a partial plasma etch process, the thermal process energy absorbed per second by the wafer (in this case imparted to the wafer by a focus plasma beam) is on the order of tens of watts (e.g. about 10 W to about 100 W) and may be taken as 63 W for the purposes of this example.

The above equations can be used to estimate the amount of heat that a substrate holder can dissipate via radiative cooling. For conceptual purposes, the surface area of the substrate holder may be assumed to be about 0.15 m² (corresponding to a 300 mm diameter chuck that is 10 mm thick and does not consider the effects of the wafer itself, which may increase or decrease the actual cooling). A common material for a wafer chuck is polished aluminum, which has an emissivity in the range of about 0.039 to about 0.057.

Simple calculations using the above equations with ε=0.057 at 473 K (−200° C.) and recognizing that σ is about 5.67×10⁻⁸ W/m²/K⁴ show that the radiated heat energy per second by the substrate holder is about 24 W, which shows that radiative heat transfer may be a substantial percentage of the heat dissipated at 200° C., but would not be sufficient to prevent additional heating of the substrate without other cooling mechanisms.

By comparison, hard anodized aluminum has a much higher emissivity of 0.9. The same calculation assuming hard anodized surfaces with ε=0.9 results in about 380 W of radiated heat at 200° C., a much higher value than polished aluminum and an order of magnitude higher than the heat transferred to the wafer via processing. Increasing the substrate temperature to about 350° C. results in over 1000 W of dissipated heat. In various embodiments, the substrate holder may be configured to provide sufficient radiative heat dissipation to operate the substrate holder at a temperature lower than 350° C. However, in view of the above calculations, it may be advantageously feasible to operate a substrate holder with intermediate to high emissivity at a relatively low temperature (200° C. or lower) while providing sufficient radiative heat dissipation to provide a good balance and achieve good temperature control.

Therefore, the inventors have discovered that a substantially steady substrate temperature can be attained by heating the substrate holder (e.g. using a heater integrated into a wafer chuck in thermal contact with a wafer) to a temperature that is hot enough to cause radiative heat dissipation that is higher than the absorption of thermal energy from the processing source (e.g. a plasma). When the processing source begins transferring heat to the substrate (e.g. the source is turned on and impinges on surfaces of a wafer), a temperature control system can reduce heating (e.g. reduce current flow to a heater), such that heat transfer to and from the support assembly is balanced and the temperature is maintained (i.e. a steady temperature).

By tailoring various design parameters such as surface area and emissivity of surface materials, the steady temperature may advantageously be within the acceptable temperature range for a chosen process. This method of cooling may also advantageously improve cross-wafer temperature uniformity and wafer-to-wafer temperature uniformity. A further benefit of this flexibility may be to enable the omission of other cooling mechanisms from the support assembly, whether by preference or because the other cooling methods were impractical for a given application.

For example, the solution described herein may be suitable for applications where it may be difficult or impossible to achieve controlled and uniform wafer temperature using other cooling methods such as liquid cooling techniques or gas cooling techniques. One such application may be raster processes (i.e. processes that utilize a scanning pattern to expose portions of a substrate as opposed to exposing large regions of the substrate at a time). Raster processes, may move the substrate (e.g. using a mechanical arm) relative to a stationary exposure region (e.g. a stationary localized plasma source) which can make liquid cooling implementation difficult.

Additionally, since the substrate is being heated during processing, the radiative cooling method may have the additional advantage of increasing throughput since the rate of many processes (e.g. etching) is increased with temperature. This may also have the simultaneous benefit of preventing outgassing of adsorbed compounds from the substrate, such as sulfur fume outgassing, reducing or eliminating the need for a post-processing heat treatment that is sometimes used.

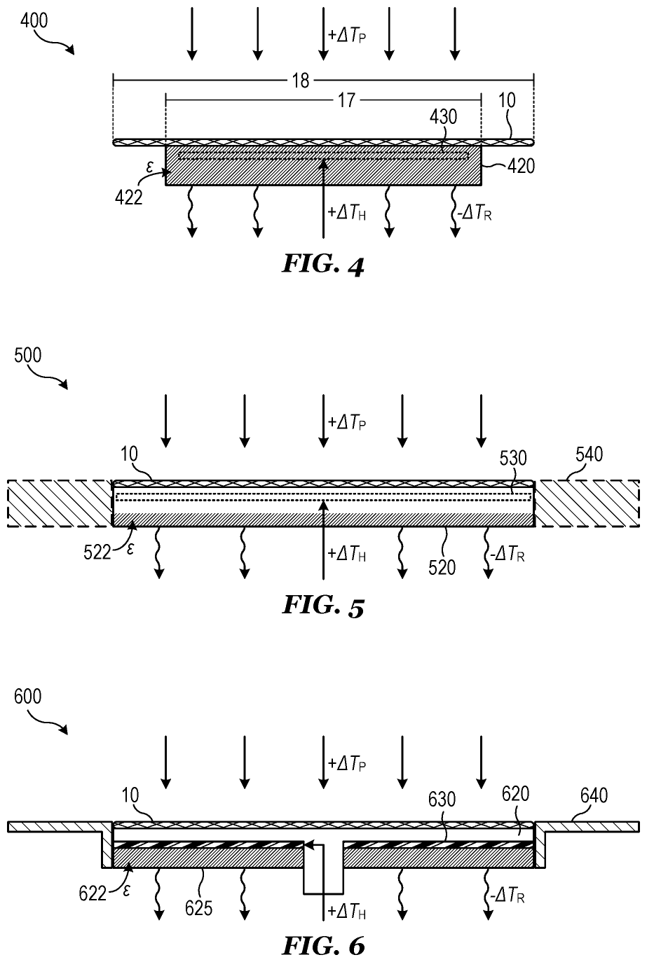

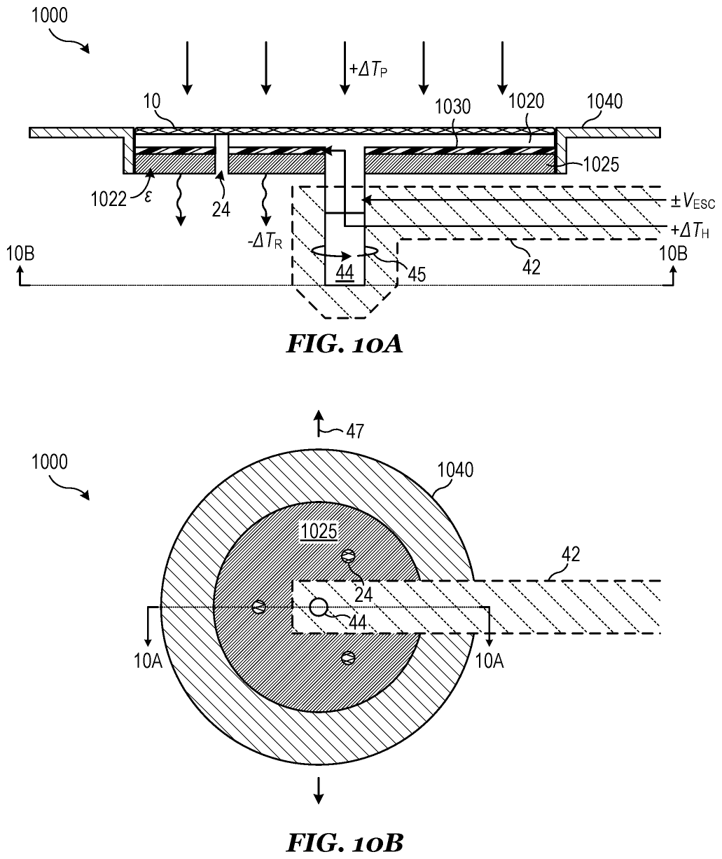

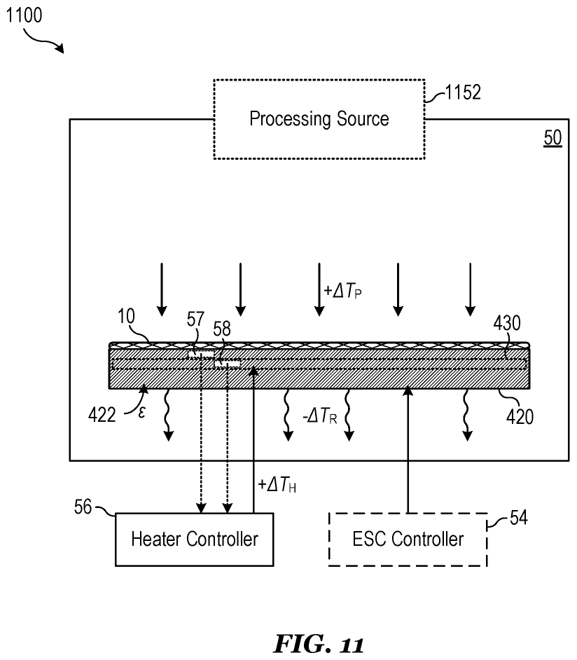

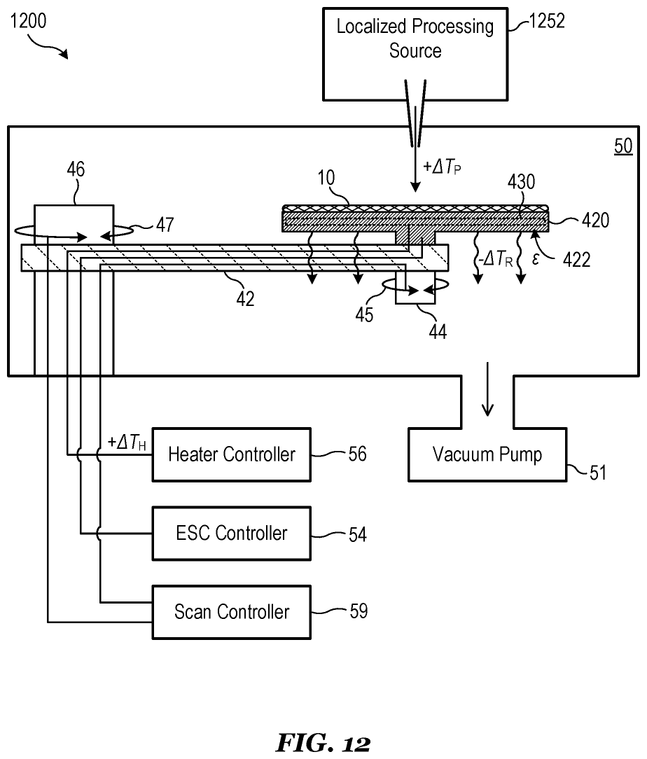

Embodiments provided herein describe various methods, apparatuses, and systems for substrate processing, and in particular, to methods, apparatuses, and systems that use radiative cooling. FIG. 3 is used to describe an example method of cooling a substrate during processing. An example support assembly utilizing radiative cooling is described using FIG. 4. Five more example support assemblies are described using FIGS. 5-9 while FIGS. 10A and 10B are used to describe an example support assembly including a mechanical arm. An example processing system is then described using FIG. 11 and another processing system that uses a localized processing source is described using FIG. 12.

FIG. 3 illustrates a method of cooling a substrate during processing by heating the substrate in accordance with embodiments of the invention. The method of FIG. 3 may be combined with other methods and performed using the systems and apparatuses as described herein. Although shown in a logical order, the arrangement and numbering of the steps of FIG. 3 are not intended to be limited. The method steps of FIG. 3 may be performed in any suitable order or concurrently with one another as may be apparent to a person of skill in the art.

Referring to FIG. 3, a method 300 of cooling a substrate during processing includes a step 301 of processing a substrate supported by a substrate holder. The substrate is heated by the processing. For example, the process may be an etching process and is a plasma process in some embodiments. The process may be a global process that processing all desired regions of a substrate simultaneously or a localized process that only processes a portion of the substrate at any given time (e.g. scanning processes using a focused beam, such as a plasma beam, ion beam, electron beam, laser beam, and the like).

Concurrently with processing the substrate in step 301, the substrate is cooled by radiating heat from the substrate holder in step 302. Also while processing the substrate in step 301, a steady temperature of the substrate is maintained in step 303 by heating the substrate holder such that heat transferred from the substrate, first by conducting into the substrate holder, then conducting through the holder to the surfaces of the holder and then by radiating heat from the substrate holder substantially balances heat transferred to the substrate by processing the substrate and by heating the substrate holder.

Since step 301, step 302, and step 303 are all concurrently performed while the substrate is being processed, these steps may be considered a processing phase 304 of the method 300. During the processing phase 304, the substrate holder is intentionally heated to a higher temperature than may otherwise be attained during processing in order to cool the substrate and maintain a steady temperature.

Optionally, before processing the substrate (i.e. while the substrate is being supported by the substrate holder, but before step 301 of processing the substrate), the substrate may be maintained at the steady temperature in step 305 by heating the substrate holder such that heat transferred from the substrate via thermal radiation of the substrate holder substantially balances heat transferred to the substrate by heating the substrate holder.

Since no heat is being added to the substrate via processing, step 305 may involve transferring more heat to the substrate to maintain the steady temperature than during step 303. For example, before processing the substrate during step 305, the substrate may be maintained at the steady temperature by heating the substrate holder to transfer thermal energy at a first rate and the heating of the substrate holder may be reduced in step 303 while processing the substrate to transfer thermal energy at a second rate that is less than the first rate to compensate for the heat transferred to the substrate by processing the substrate.

Therefore, it may be useful to first operate the substrate holder at a temperature where the radiative heat dissipation is higher than the heat addition from the thermal energy of the processing of the substrate (e.g. the plasma etching) so that the substrate holder (e.g. the chuck) temperature will not continue to rise even with the heater turned off. It may also be useful to operate at a temperature even higher than this so that the heat dissipation when the heater is turned off is of a similar magnitude as the heat addition when the heater is turned on.

After the processing phase 304, the substrate may be removed from the substrate holder in step 306. Depending on the value of the steady temperature and the post-process requirements for the substrate, an additional optional step of cooling the substrate may be utilized after processing and removal of the substrate from the substrate holder.

An optional step 307 of maintaining the substrate holder at the steady temperature by heating the substrate holder may be performed after removing the substrate. For example, step 307 may be incorporated when the processing is to be repeated on subsequent wafers (shown as step 308). The subsequent substrate may be placed or otherwise provided into the system such that it is supported by the substrate holder (step 309). Step 301, step 302, and step 303 may then be performed the subsequent substrate as well as future substrates as desired. Since the steady temperature is maintained at all times before, during and after processing wafer-to wafer temperature uniformity is advantageously maintained.

When a substrate is initially introduced to the system (e.g. placed on the substrate holder), the substrate may not be the same temperature as the substrate holder (e.g. cooler or even warmer than the steady temperature). In this case, maintaining also encompasses bringing the substrate to the steady temperature by heating the substrate with the heater or by cooling the substrate through radiative cooling of the substrate holder.

The steady temperature may be maintained to within a tolerance. The tolerance may include various measurements of uniformity such as cross-wafer temperature variation, process temperature variation (the amount that the average temperature of the substrate varies during processing), wafer-to-wafer temperature variation, and others. In some embodiments, the tolerance of the cross-wafer temperature variation is less than about 4° C. and is less than about 2° C. in one embodiment. In one embodiment, the tolerance of the process temperature variation is less than about 1° C. The tolerance of the wafer-to-wafer temperature variation may be less than about 2° C. and is less than about 1° C. in one embodiment.

Various features may be employed may facilitate the performance of the radiating cooling methods using a substrate holder. In one embodiment, the substrate holder fully contacts the supported substrate (e.g. a backside surface of the substrate) from center to edge. As previously discussed in reference to FIG. 2B, this may advantageously improve cross-wafer temperature uniformity.

As discussed in the preceding, significant radiative cooling can be achieved even for substrate holders with low emissivity. However, incorporating materials at surfaces of the substrate holder that have higher emissivity may advantageously improve the efficiency of the radiative cooling and may, at times, be necessary to bring the steady temperature to within a desired range suitable for a given type of processing. So-called high emissivity (HE) materials may be used, for example, but materials of intermediate emissivity may also afford an advantage over the bare machined or polished metal surfaces conventionally employed in processing systems.

In some embodiments, the substrate is heated with an electric heater and is heated with a resistive heater in one embodiment. A heater may be integrated into or disposed on the substrate holder. In one embodiment, the heater is a flexible resistive heater. In other embodiments, the heater is another type of resistive heater such as a cartridge heater or a ceramic heater. A resistive heating element can be embedded directly into the ceramic holder material by forming the ceramic around it. Additionally or alternatively, the heater may be an external heating source such as a radiative heat source.

In some embodiments, the substrate may be monitored by measuring the temperature while processing the substrate. The heating of the substrate holder may then be dynamically adjusted in response to variations of the measured temperature detected while monitoring the measured temperature. This may advantageously allow the steady temperature to be continuously maintained even when conditions during processing fluctuate. The substrate (e.g. a silicon wafer) may also have variable emissivity depending on factors such as the thin films and devices on the surface and embedded within it. Dynamic adjustment of the heat supplied by the heater may also beneficially compensate for these variations in the heat dissipation of the substrate itself.

Achievement of temperature control require the ability to add heat to increase temperature as well as the ability to dissipate heat when the temperature is too high. Thus, control of the temperature (i.e. the steady temperature) is attained when the heat addition and heat dissipation mechanisms are relatively balanced. In this case, the dissipation of heat may be primarily through radiative heat transfer from outward facing surfaces of the support assembly (e.g. through a vacuum that surrounds it and on to the walls of a processing chamber).

To this end, the steady temperature may be controlled using a feedback control system coupled to the heater (e.g. using temperature monitoring devices) to maintain the chuck, and thus the wafer sitting on it, at a constant temperature. For example, one or more resistance temperature detectors (RTDs) or other temperature monitoring devices such as thermocouples or thermistors may be used to monitor temperature at various points on the substrate holder and the heater as well as any other locations within the processing system that may be useful for maintaining the steady temperature. In some implementations, separate heaters for different zones of the wafer may also be utilized which may beneficially expand the fine control over the cross-wafer temperature uniformity.

In various embodiments, the heat transferred to the substrate by the heater as well as the heat transferred to the substrate by processing the substrate is predominantly dissipated (e.g. balanced by) radiative heat transfer to the surrounding chamber. For example, the substrate processing may be performed under vacuum (e.g. high vacuum, ultra-high vacuum, but also other higher and lower vacuum regimes) removing the convective heat pathway into the processing chamber.

Additionally, as noted above, cooling contributions from other mechanisms of heat transfer such as liquid cooling of the substrate holder, thermal conduction through the substrate holder, and cooling of the substrate via a background gas may be absent or minimal. In some embodiments, no heat is transferred from the substrate using a liquid while processing the substrate. In one embodiment, substantially no heat is transferred from the substrate via convection while processing the substrate. That is, the substrate is not cooled using fluids (liquid or gas phase) any incidental cooling by processing gases, etc. are negligible (e.g. less than 10% of the total cooling) compared to the radiative cooling from the substrate holder.

The radiating cooling methods described herein may be advantageous for a variety of reasons for both stationary and non-stationary support assemblies. However, stationary support assemblies (e.g. chucks used for processing that sit stationary in a processing chamber) may be easier to cool using fluids (e.g., water, gases, heat transfer fluids) or by thermal conduction to the outside of the processing chamber (where it is more easily dissipated to the ambient).

In various embodiments, the processing of the substrate may be a localized processing technique such as a scanning (e.g. a raster) technique. In one embodiment, processing the substrate includes moving the substrate laterally relative to a stationary localized processing source. For example, the lateral movement may be accomplished using an arm attached to the substrate holder. While the substrate is being moved (perhaps quite rapidly), the substrate is being both heated and cooled to maintain the substrate at the steady temperature.

FIG. 4 illustrates an example support assembly including a substrate holder and a heating element configured to radiatively cool a substrate in accordance with embodiments of the invention. The support assembly of FIG. 4 may be used to perform any of the methods described herein, such as the method of FIG. 3, for example.

Referring to FIG. 4, a support assembly 400 includes a substrate 10 (e.g. a wafer) supported (e.g. immobilized) by a substrate holder 420. In various embodiments, the substrate holder 420 is a chuck. In one embodiment, the substrate holder 420 is an ESC. The substrate holder 420 may be configured to provide thermal conduction from the substrate 10 contact surface with the substrate holder 420 to exposed surfaces of the (e.g., high emissivity surfaces of the substrate holder 420, such as the backside) to radiate away excess heat gained by the substrate 10 by processing the substrate 10.

The substrate holder 420 includes a heater 430, which may be disposed in or on the substrate holder 420. The heater 430 is configured to transfer heat (conceptually illustrated by a positive change in temperature+ΔT_{H}, although it should be noted that heat transfer is more specifically a transfer of thermal energy Q which results in an increase in temperature that is dependent on properties of the material absorbing the thermal energy such as specific heat capacity) to the substrate holder 420. The substrate 10 is in thermal contact with the substrate holder 420 thereby facilitating the further transfer of the heat supplied by the heater 430 to the substrate 10.

An emissive material 422 (e.g. comprising metal such as aluminum, a ceramic material, or other materials) is included in the substrate holder 420. As previously discussed, the emissive material 422 may have any emissivity e, the exact value of which may depend on the design considerations of a given application. For example, the substrate holder 420 is configured to cool the substrate 10 so that the heat transferred to the substrate 10 during processing (+ΔT_{P}) and by the heater 430 is balanced by the heat transferred away from the substrate 10 by the radiative cooling (−ΔT_{R}) of the substrate holder 420. This is illustrated in FIG. 4 (and elsewhere) using arrows pointing towards and away from the substrate 10. In this way, the substrate 10 may be maintained at a steady temperature during processing.

Despite no specific requirement for the emissivity e of the emissive material 422, it may be advantageous for the substrate holder 420 to be formed from or include materials that have higher emissivity than the bare machined or polished metal and/or light-colored surfaces that may be conventionally employed. For example, the emissive material 422 may have a rough surface in some embodiments. In some embodiments, the emissive material 422 is a dark-colored material, such as silicon carbide or hard anodized aluminum (which may have a dark slate grey surface). For instance, black or dark-colored surfaces can have more than 10 times the radiative heat dissipation of a shiny silver surface.

Although the substrate holder 420 is shown as including the emissive material 422 throughout its entirety, the emissive material 422 may also be implemented as a coating on all or some surfaces of the substrate holder 420. More than one emissive material may be included, and substrate holder 420 may even include emissivity gradients to further tailor the temperature profile of the substrate 10. The emissive material 422 may also be implemented as materials separate from the primary material of the substrate holder 420 and suitably attached to the substrate holder 420.

In various embodiments, the heat generated by processing of the substrate 10, the heat generated by the heater 430, and the radiative cooling by the substrate holder 420 are the only significant sources of heat transfer to and from the substrate 10. However, in other embodiments, other additional forms of heating and cooling may be present. The heater 430 may further be used to accordingly balanced the total heat transfer to and from the substrate 10 during processing.

The substrate holder 420 may be any desired size and shape, the specifics of which may depend on the substrate 10 that is being processed. In some embodiments, the substrate holder 420 is circular. A major dimension of the substrate holder 420 (e.g. a substrate holder diameter 17) may by any size relative to a major dimension of substrate 10 (e.g. a substrate diameter 18). In some embodiments, the substrate holder diameter 17 is chosen such that it is at least as large as the substrate diameter 18. That is, the side of the substrate holder 420 (e.g. a chuck) facing the substrate 10 may entirely overlap the backside surface of the substrate 10 (which is a major surface of the substrate 10). As previously discussed, this may afford additional advantages in cross-wafer temperature uniformity.

It is of course possible for the substrate holder diameter 17 to be greater than the substrate diameter 18. In one embodiment, the substrate holder diameter 17 is about equal to the substrate diameter 18. The substrate holder diameter 17 may also be slightly smaller than the substrate diameter 18 while achieving the same or similar benefits, the beneficial effects of having similarly sized substrate and substrate holder gradually diminishing as the substrate holder diameter 17 is decreased relative to the substrate diameter 18. This may advantageously prevent cross-wafer temperature non-uniformity that may be caused by additional cooling of the substrate holder 420 that extends beyond the extend of the substrate 10.

FIG. 5 illustrates an example support assembly including a substrate holder supporting a substrate and including a material with an emissivity that is higher than the emissivity of the material facing the substrate in accordance with embodiments of the invention. The support assembly of FIG. 5 may be a specific implementation of other support assemblies described herein such as the support assembly of FIG. 4, for example. Similarly labeled elements may be as previously described.

Referring to FIG. 5, a support assembly 500 includes a substrate 10 supported by a substrate holder 520. It should be noted that here and in the following a convention has been adopted for brevity and clarity wherein elements adhering to the pattern [x10] may be related implementations of a substrate holder in various embodiments. For example, the substrate holder 520 may be similar to the substrate holder 420 except as otherwise stated. An analogous convention has also been adopted for other elements as made clear by the use of similar (but not necessarily identical) terms in conjunction with the aforementioned numbering system.

The support assembly 500 may be similar to the support assembly 400 of FIG. 4 except for a difference between the emissivity of a material at an exposed surface of the substrate holder 520 and the emissivity of material of the substrate holder 520. That is, an emissive material 522 with emissivity e is included in the substrate holder 520 that has a higher emissivity than other material of the substrate holder 520. For example, the material of the substrate holder 520 at an upper side of the substrate holder 520 that is facing the substrate 10 may have a lower emissivity than the emissivity e of the emissive material 522 at an exposed lower side of the substrate holder 520.

This may be advantageous for various reasons. For instance, the temperature profile of the substrate 10 may be advantageously tailored by the emissive properties of surfaces of the substrate holder 520. Materials of the substrate holder 520 other than the emissive material 522 may be also chosen for reasons other than emissivity. Including the emissive material 522 with higher emissivity may beneficially allow selection of other materials of the substrate holder 520 without prioritizing their emissive properties.

The emissive material 522 may be a separate material attached to the substrate holder 520. In come cases, the emissive material 522 may be a coating or film that is sprayed, painted, or otherwise applied to an existing surface of the substrate holder 520. In various embodiments, the emissive material 522 formed by treating an existing surface of the substrate holder 520. In one embodiment, the emissive material 522 is formed by hard anodizing the material of the substrate holder 520. For example, the substrate holder 520 may be formed from aluminum (e.g. including polished aluminum surfaces) and the emissive material 522 may be hard anodized aluminum.

Other surface coatings such as Nedox® coatings by General Magnaplate have very dark to black surfaces which may have high emissivity. These (and other coatings) may provide additional benefits in addition to emissive properties such as enhanced resistance to attack by various chemical species.

An optional overscan shield 540 may be included to extend the surface of the substrate 10. For example, the overscan shield 540 may be mounted to the perimeter of the substrate holder 520. Alternatively, the overscan shield 540 may be integrated with the substrate holder 520 or extend partially or fully under the substrate holder 520. The overscan shield 540 differs from the overscan shield 15 shown in FIG. 1 in that it does not overlap lower surfaces of the substrate holder 520 that are vertically aligned with the substrate 10.

The overscan shield 540 may also provide an advantage for increasing the heat dissipation by increasing the surface area available for radiative heat transfer. However, in some implementations, it could exacerbate cross-wafer temperature non-uniformity by preferentially dissipating heat from around the perimeter of the chuck and thus cooling the perimeter more than the center. Therefore, it may be advantageous to provide a thermally insulating material or a gap between the overscan shield 540 and the rest of the substrate holder, choosing nonconductive material for the overscan shield itself, or mounting the chuck assembly in such a way that the heat is not preferentially removed from the chuck perimeter. For example, a thermally insulating material may be included to reduce the effects a lateral thermally conductive pathway at the edges of the substrate 10.

FIG. 6 illustrates an example support assembly including a substrate holder and a heating element disposed between the substrate holder and a bottom cover in accordance with embodiments of the invention. The support assembly of FIG. 6 may be a specific implementation of other support assemblies described herein such as the support assembly of FIG. 4, for example. Similarly labeled elements may be as previously described.

Referring to FIG. 6, a support assembly 600 includes a substrate 10 supported by a substrate holder 620. The support assembly 600 may be similar to the support assembly 500 of FIG. 5 except for including a plate 625 that includes or is formed from an emissive material 622. The plate 625 is attached to the substrate holder 620. For example, the plate 625 may be attached to a lower surface of the substrate holder 620. This may have the advantages of promoting temperature uniformity and conducting heat to a surface of the support assembly 600 for radiation of that heat through a vacuum and on to surrounding walls of a processing chamber.

A heater 630 may be disposed between the substrate holder 620 and the plate 625, as shown. The plate 625 may be used to clamp the heater 630 in place. Additionally, the/625 may aid in the lateral spreading heat. In one embodiment, the heater 630 may be a flexible resistive heater made by sandwiching electrical conductor traces between two insulating layers, such as polyimide. However, other types of resistive electric heaters, such as cartridge heaters or ceramic heaters can also be used.

FIG. 7 illustrates an example support assembly including a substrate holder and an overscan shield at least partially underlying a full-diameter substrate holder in accordance with embodiments of the invention. The support assembly of FIG. 7 may be a specific implementation of other support assemblies described herein such as the support assembly of FIG. 4, for example. Similarly labeled elements may be as previously described.

Referring to FIG. 7, a support assembly 700 includes a substrate 10 supported by a substrate holder 720 including a heater 730. The support assembly 700 may be similar to the support assembly 600 of FIG. 6 except that an overscan shield 740 is included that extends partially over a lower surface of a plate 725 attached to the substrate holder 720. The overlap may be included, for example, as a method of attaching the overscan shield 740 to the substrate holder 720. The extension may advantageously not overlap the plate 725 at all points along the edge of plate 725. Rather, relatively thin extensions may overlap the plate 725 so as to avoid substantially interfering with the radiative cooling efficacy of the emissive material 722 at the edge of the plate 725.

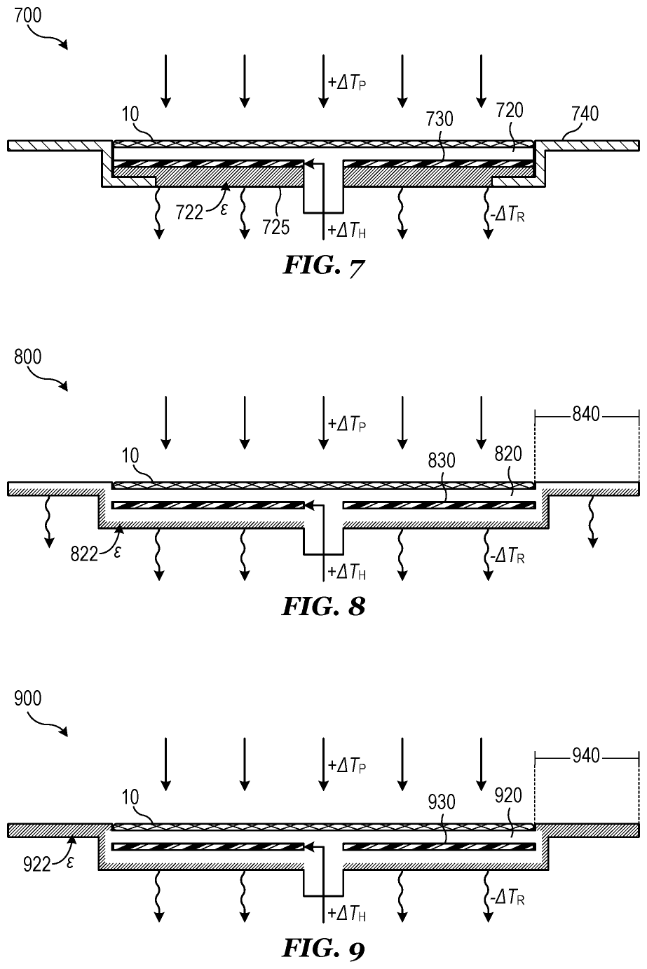

FIG. 8 illustrates an example support assembly including a substrate holder with an integrated overscan shield in accordance with embodiments of the invention. The support assembly of FIG. 8 may be a specific implementation of other support assemblies described herein such as the support assembly of FIG. 4, for example. Similarly labeled elements may be as previously described.

Referring to FIG. 8, a support assembly 800 includes a substrate 10 supported by a substrate holder 820 including a heater 830. The support assembly 800 may be similar to the support assembly 500 of FIG. 5 except that an overscan shield 840 may be included that is integrated with the substrate holder 820. In this particular example, an emissive material 822 may be included on some or all of the lower surfaces of the substrate holder 820 (which includes lower surfaces of the overscan shield 840).

FIG. 9 illustrates another example support assembly including a substrate holder with an integrated overscan shield in accordance with embodiments of the invention. The support assembly of FIG. 9 may be a specific implementation of other support assemblies described herein such as the support assembly of FIG. 4, for example. Similarly labeled elements may be as previously described.

Referring to FIG. 9, a support assembly 900 includes a substrate 10 supported by a substrate holder 920 including a heater 930. The support assembly 900 may be similar to the support assembly 800 of FIG. 8 except that an emissive material 922 is also included on upper surfaces of an overscan shield 940 integrated with the substrate holder 920. That is, the overscan shield 940 may include an exposed upper surface extending laterally from outer edges of the substrate 10 that includes the same emissive material 922 that is included on the lower surfaces of the overscan shield 940 and the substrate holder 920.

FIGS. 10A and 10B illustrate an example support assembly including a substrate holder attached to a mechanical arm configured to move the substrate laterally relative to a processing source during processing in accordance with embodiments of the invention, where FIG. 10A is a side view of the support assembly and FIG. 10B illustrates a bottom view of the support assembly. The support assembly of FIGS. 10A and 10B may be a specific implementation of other support assemblies described herein such as the support assembly of FIG. 4, for example. Similarly labeled elements may be as previously described.

Referring to FIGS. 10A and 10B, a support assembly 1000 includes a substrate 10 supported by a substrate holder 1020 including a heater 1030. In one embodiment (as shown) the substrate holder 1020 may be an ESC that receives clamping voltages V_{ESC} to immobilize the substrate 10 on the substrate holder 1020. The ESC may advantageously prevent the substrate 10 from moving even during rapid acceleration and deceleration (e.g. lateral acceleration of 5g with no detectable slipping).

An overscan shield 1040 is attached to the substrate holder 1020. An emissive material 1022 is included in at least a plate 1025, attached to the substrate holder 1020. A mechanical arm 42 is attached to the substrate holder 1020. The mechanical arm 42 is configured to move the substrate 10 during processing. For example, the mechanical arm 42 may be configured to cause lateral motion 47 of the substrate 10 relative to a stationary localized processing source. Additionally or alternatively, the mechanical arm 42 may be configured to cause rotational motion 45, using a rotary drive 44, for example.

The mass of the support assembly 1000 including the substrate holder 1020, the heater 1030, the plate 1025, and the overscan shield 1040 may be advantageously minimized while still providing the desired radiative cooling capability in order to avoid complicated and expensive modifications to motors, gear boxes, drive and control electronics of the mechanical arm 42 as they may exist in implementations without the radiative cooling capability.

The substrate holder 1020 may also include one or more lift-pin holes 24 through the substrate holder 1020 (and potentially through the heater 1030 and/or plate 1025 as shown). The lift-pin holes 24 may be configured to allow passage of substrate lift pins which are actuated to lift the substrate 10 off of the surface of the substrate holder 1020 so it can be picked up by a transfer robot end effector which accesses the back side of the substrate 10 for handling. Similarly, the lift pins may be actuated downward to lower the next substrate 10 onto the surface of the substrate holder 1020.

FIG. 11 illustrates a substrate processing apparatus including a substrate holder configured to radiatively cool a substrate while the substrate is being processed by heating the substrate holder during the processing in accordance with embodiments of the invention. The substrate processing apparatus may be used to perform any of the methods described herein, such as the method of FIG. 3, for example. Similarly labeled elements may be as previously described.

Referring to FIG. 11, a substrate processing apparatus 1100 includes a support assembly disposed in a processing chamber 50 and including the substrate holder 420, which may be as previously described. The processing chamber 50 is a processing chamber 50 in various embodiments. When the substrate holder 420 operates in a vacuum, the heat added by the heater 430 as well as the heat conducted from the substrate 10 to the substrate holder 420 from a processing source 1152 may be advantageously dissipated from the substrate holder 420 primarily through radiative heat transfer to surrounding walls of the processing chamber 50.

For implementations that utilize an ESC as the substrate holder 420, an ESC controller 54 may be included to control the clamping of the substrate 10 (e.g. a wafer) to the surface of the ESC.

A heater controller 56 is included in the substrate processing apparatus 1100 to maintain the substrate 10 at a steady temperature. The heater controller 56 may be configured to control the application of power to the heater 430, such as 1-phase 208 VAC power.

A substrate temperature detector 57 may be included near or in physical contact with the substrate 10. The substrate temperature detector 57 may be configured to monitor temperature at the substrate 10. A heater temperature detector 58 may be included at the heater 430. The heater temperature detector 58 may be configured to monitor temperature at the heating element. One or both of the substrate temperature detector 57 and the heater temperature detector 58 may also be used for over-temperature monitoring for safety purposes. The substrate temperature detector 57 and the heater temperature detector 58 may be implemented using any suitable temperature detector, such as RTDs, for example. Other potentially suitable temperature detectors include thermocouples and thermistors, among others.

Additional temperature detectors may also be included. For example, if the heater 430 and the heater controller 56 are configured for control over regions of the substrate 10, additional temperature detectors may be included to facilitate the regional temperature control. Moreover, additional temperature detectors may also be included to increase the accuracy of the measured temperature at the substrate 10 and or the heater 430.

FIG. 12 illustrates another example substrate processing apparatus configured to radiatively cool a substrate while the substrate is being processed where the processing utilizes a mechanical arm to move the substrate laterally relative to a processing source in accordance with embodiments of the invention. The substrate processing apparatus may be a specific implementation of over substrate support apparatuses described herein, such as the substrate support apparatus of FIG. 11, for example. Similarly labeled elements may be as previously described.

Referring to FIG. 12, a substrate processing apparatus 1200 includes a support assembly disposed in a processing chamber 50 and including the substrate holder 420, which may be as previously described. The substrate processing apparatus 1200 may be a similar to the substrate processing apparatus 1100 of FIG. 11 except that the processing source 1152 is specifically a localized processing source 1252 and the support assembly includes appropriate additional equipment (e.g. the mechanical arm 42, the rotary drive 44, and a lateral motion rotary drive 46) to enable the substrate 10 to be moved relative to the processing source 1152.

Additionally, substrate processing apparatus 1200 includes a vacuum pump 51 and the processing chamber 50 is specifically a vacuum processing chamber. A scan controller 59 is also include to control the rotary drive 44 and the lateral motion rotary drive 46 and cause the substrate 10 to move relative to the processing source 1152.

Example embodiments of the invention are summarized here. Other embodiments can also be understood from the entirety of the specification as well as the claims filed herein.

Example 1. A method of cooling a substrate during processing, the method including: processing a substrate supported by a substrate holder, the substrate being heated by the processing; cooling the substrate while processing the substrate by radiating heat from the substrate holder; and maintaining the substrate at a steady temperature to within a tolerance while processing the substrate by heating the substrate holder such that heat transferred from the substrate by radiating heat from the substrate holder substantially balances heat transferred to the substrate by processing the substrate and by heating the substrate holder.

Example 2. The method of example 1, further including: before processing the substrate, maintaining the substrate at the steady temperature by heating the substrate holder such that heat transferred from the substrate via thermal radiation of the substrate holder substantially balances heat transferred to the substrate by heating the substrate holder.

Example 3. The method of one of examples 1 and 2, further including: maintaining the substrate holder at the steady temperature after removal of the substrate by heating the substrate holder; processing a subsequent substrate supported by the substrate holder, the subsequent substrate being heated by processing the subsequent substrate; cooling the subsequent substrate by radiating heat from the substrate holder while processing the subsequent substrate; and maintaining the subsequent substrate at the steady temperature while processing the subsequent substrate by heating the substrate holder.

Example 4. The method of example 2, where: maintaining the substrate holder at the steady temperature before processing the substrate includes heating the substrate holder to transfer thermal energy at a first rate; and maintaining the substrate at the steady temperature to within the tolerance while processing includes reducing heating of the substrate holder to transfer thermal energy at a second rate less than the first rate to compensate for the heat transferred to the substrate by processing the substrate.

Example 5. The method of one of example 1 to 4, where the tolerance includes a cross-wafer temperature variation less than about 4° C.

Example 6. The method of one of examples 1 to 5, where the tolerance includes a process temperature variation less than about 1° C.

Example 7. The method of one of examples 1 to 6, further including: monitoring the substrate by measuring the temperature while processing the substrate; and dynamically adjusting the heating of the substrate holder in response to detecting variations of the measured temperature to continue to maintain the substrate at the steady temperature.

Example 8. The method of one of examples 1 to 7, where no heat is transferred from the substrate using a liquid while processing the substrate.

Example 9. The method of example 8, where substantially no heat is transferred from the substrate via convection while processing the substrate.

Example 10. The method of one of examples 1 to 9, where processing the substrate includes moving the substrate laterally relative to a stationary localized processing source using an arm attached to the substrate holder while both cooling the substrate and heating the substrate holder to maintain the substrate at the steady temperature.

Example 11. A substrate holder including: a chuck configured to immobilize a substrate at a first side of the chuck including a first material; a heater disposed on or in the chuck and configured to heat the substrate; and a second material disposed at a second side of the chuck opposing the first side, the second material including an exposed surface configured to cool the substrate by emitting thermal radiation, the emissivity of the first material being lower than the emissivity of the second material.

Example 12. The substrate holder of example 11, where the substrate includes a major surface, and where the first side of the entirely chuck overlaps the major surface of the substrate.

Example 13. The substrate holder of one of examples 11 and 12, where the second material forms a plate attached at the second side of the chuck.

Example 14. The substrate holder of one of examples 11 to 13, where the second material is a coating or film covering the second side of the chuck.

Example 15. The substrate holder of example 14, where the coating or film is a hard anodized coating.

Example 16. The substrate holder of one of example 14 and 15, where the coating or film is a high emissivity coating configured to also provide chemical resistance.

Example 17. The substrate holder of one of examples 11 to 16, where the second material is a high emissivity ceramic.

Example 18. A substrate processing apparatus including: a vacuum chamber; an electrostatic chuck (ESC) disposed in the vacuum chamber and having no liquid cooling mechanism, the ESC being configured to clamp a substrate to an upper surface of the ESC facing a localized processing source; a heater integrated with the ESC and configured to heat the substrate while processing the substrate; and a mechanical arm attached to the ESC and configured to move the substrate laterally relative to the localized processing source to process the substrate.

Example 19. The substrate processing apparatus of example 18, including: a first material including the upper surface of the ESC; and a second material including a lower surface of the ESC, the lower surface being an exposed surface configured to cool the substrate by emitting thermal radiation, the emissivity of the first material being lower than the emissivity of the second material.

Example 20. The substrate processing apparatus of example 19, further including: an overscan shield including an exposed upper surface extending laterally from outer edges of the substrate, the exposed upper surface also including the second material.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of cooling a substrate during processing, the method comprising:
processing a substrate supported by a substrate holder, the substrate being heated by the processing;
cooling the substrate while processing the substrate by radiating heat from the substrate holder; and
maintaining the substrate at a steady temperature to within a tolerance while processing the substrate by heating the substrate holder such that heat transferred from the substrate by radiating heat from the substrate holder substantially balances heat transferred to the substrate by processing the substrate and by heating the substrate holder.

2. The method of claim 1, further comprising:
before processing the substrate, maintaining the substrate at the steady temperature by heating the substrate holder such that heat transferred from the substrate via thermal radiation of the substrate holder substantially balances heat transferred to the substrate by heating the substrate holder.

3. The method of claim 2, further comprising:
maintaining the substrate holder at the steady temperature after removal of the substrate by heating the substrate holder;
processing a subsequent substrate supported by the substrate holder, the subsequent substrate being heated by processing the subsequent substrate;
cooling the subsequent substrate by radiating heat from the substrate holder while processing the subsequent substrate; and
maintaining the subsequent substrate at the steady temperature while processing the subsequent substrate by heating the substrate holder.

4. The method of claim 2, wherein:
maintaining the substrate holder at the steady temperature before processing the substrate comprises heating the substrate holder to transfer thermal energy at a first rate; and
maintaining the substrate at the steady temperature to within the tolerance while processing comprises reducing heating of the substrate holder to transfer thermal energy at a second rate less than the first rate to compensate for the heat transferred to the substrate by processing the substrate.

5. The method of claim 1, wherein the tolerance comprises a cross-wafer temperature variation less than about 4° C.

6. The method of claim 1, wherein the tolerance comprises a process temperature variation less than about 1° C.

7. The method of claim 1, further comprising:
monitoring the substrate by measuring the temperature while processing the substrate; and
dynamically adjusting the heating of the substrate holder in response to detecting variations of the measured temperature to continue to maintain the substrate at the steady temperature.

8. The method of claim 1, wherein no heat is transferred from the substrate using a liquid while processing the substrate.

9. The method of claim 8, wherein substantially no heat is transferred from the substrate via convection while processing the substrate.

10. The method of claim 1, wherein processing the substrate comprises moving the substrate laterally relative to a stationary localized processing source using an arm attached to the substrate holder while both cooling the substrate and heating the substrate holder to maintain the substrate at the steady temperature.

11. A substrate holder comprising:
a chuck configured to immobilize a substrate at a first side of the chuck comprising a first material;
a heater disposed on or in the chuck and configured to heat the substrate; and
a second material disposed at a second side of the chuck opposing the first side, the second material comprising an exposed surface configured to cool the substrate by emitting thermal radiation, the emissivity of the first material being lower than the emissivity of the second material.

12. The substrate holder of claim 11, wherein the substrate comprises a major surface, and wherein the first side of the entirely chuck overlaps the major surface of the substrate.

13. The substrate holder of claim 11, wherein the second material forms a plate attached at the second side of the chuck.

14. The substrate holder of claim 11, wherein the second material is a coating or film covering the second side of the chuck.

15. The substrate holder of claim 14, wherein the coating or film is a hard anodized coating.

16. The substrate holder of claim 14, wherein the coating or film is a high emissivity coating configured to also provide chemical resistance.

17. The substrate holder of claim 11, wherein the second material is a high emissivity ceramic.

18. A substrate processing apparatus comprising:
a vacuum chamber;
an electrostatic chuck (ESC) disposed in the vacuum chamber and having no liquid cooling mechanism, the ESC being configured to clamp a substrate to an upper surface of the ESC facing a localized processing source;
a heater integrated with the ESC and configured to heat the substrate while processing the substrate; and
a mechanical arm attached to the ESC and configured to move the substrate laterally relative to the localized processing source to process the substrate.

19. The substrate processing apparatus of claim 18, comprising:
a first material comprising the upper surface of the ESC; and
a second material comprising a lower surface of the ESC, the lower surface being an exposed surface configured to cool the substrate by emitting thermal radiation, the emissivity of the first material being lower than the emissivity of the second material.

20. The substrate processing apparatus of claim 19, further comprising:
an overscan shield comprising an exposed upper surface extending laterally from outer edges of the substrate, the exposed upper surface also comprising the second material.
